(19) United States
(12) Patent Application Publication
(10) Pub. No.: US 2013/0182399 A1
(43) Pub. Date: Jul. 18, 2013

(54) SURFACE CONTACT CARD HOLDER FOR ELECTRONIC DEVICE

(71) Applicants: CHIH-WEI CHANG, Shindian (TW); GUO-LIANG WAN, Shenzhen City (CN)

(72) Inventors: CHIH-WEI CHANG, Shindian (TW); GUO-LIANG WAN, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/599,789

(22) Filed: Aug. 30, 2012

(30) Foreign Application Priority Data
Jan. 12, 2012 (CN) 201210007981.3

(51) Int. Cl. H05K 5/00

(52) U.S. Cl. 361/759

(57) ABSTRACT

A surface contact card holder includes a housing and a latching cover. The housing defines a receiving space configured for receiving surface contact card. The latching cover covers the receiving space. One end of the latching cover is pivotally attached to the housing, another end of the latching cover is selectively latched to the housing to allow insertion and removal of the surface contact card from the housing.

### BACKGROUND

1. Technical Field

The present disclosure generally relates to card use in electronic devices, and particularly to a surface contact card holder for an electronic device.

2. Description of Related Art

With the development of wireless communication and information processing technologies, portable electronic devices such as mobile phones are widely used. Surface contact cards having special circuits are used in portable electronic devices to enhance or add to the functions of the portable electronic devices. For example, a subscriber identity module (SIM) card can be placed in a mobile phone to dedicate the mobile phone's functions to the SIM card owner. By changing SIM cards, a single mobile phone can be used by many different SIM card owners as a personal phone.

However, conventional surface contact card holder includes a tray assembled to the mobile phone. Since the internal space of the mobile phone is very limited, the tray has to occupy the internal space of the mobile phone. Additionally, the tray also needs to be assembled. Thus, the assembly process is complicated.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the surface contact card holder. Moreover, in the drawings, like reference numerals designate corresponding parts throughout the several views.

FIG. 1 is an isometric view of a surface contact card holder in accordance with an exemplary embodiment.

FIG. 2 is similar to FIG. 2, but showing a surface contact card in position on the surface contact card holder.

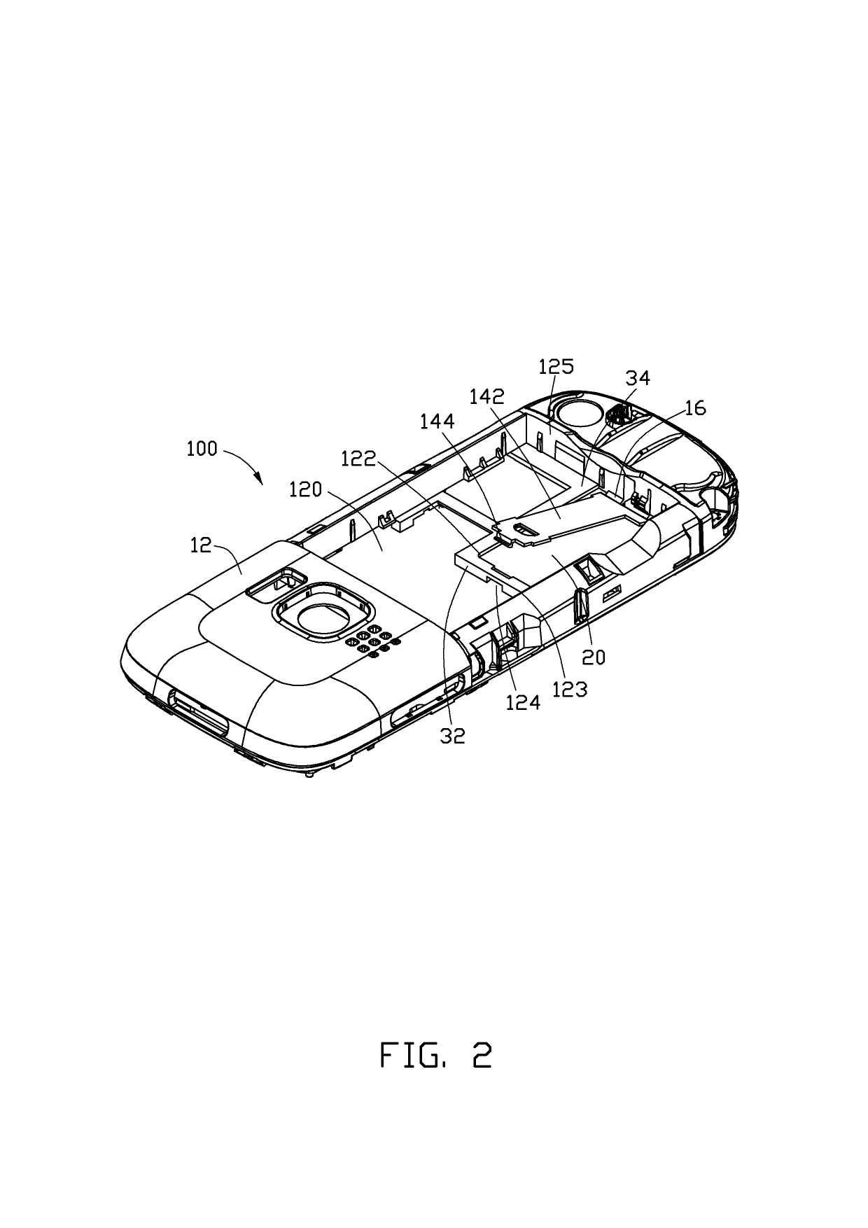

FIG. 3 is an assembled isometric view of the surface contact card holder.

FIG. 4 is a cross-sectional view of the surface contact card holder taken along line IV-IV.

FIG. 5 is an enlarged view of a circular area V of the surface contact card holder of FIG. 4.

### DETAILED DESCRIPTION

The disclosed surface contact card holder can seat surface contact cards such as SIM cards, compact flash cards (CFs) and multimedia cards (MMCs), for example. The disclosed electronic device in the exemplary embodiment is a mobile phone, and can alternatively be a PDA, camera, recorder, or other devices, while remaining well within the scope of the disclosure.

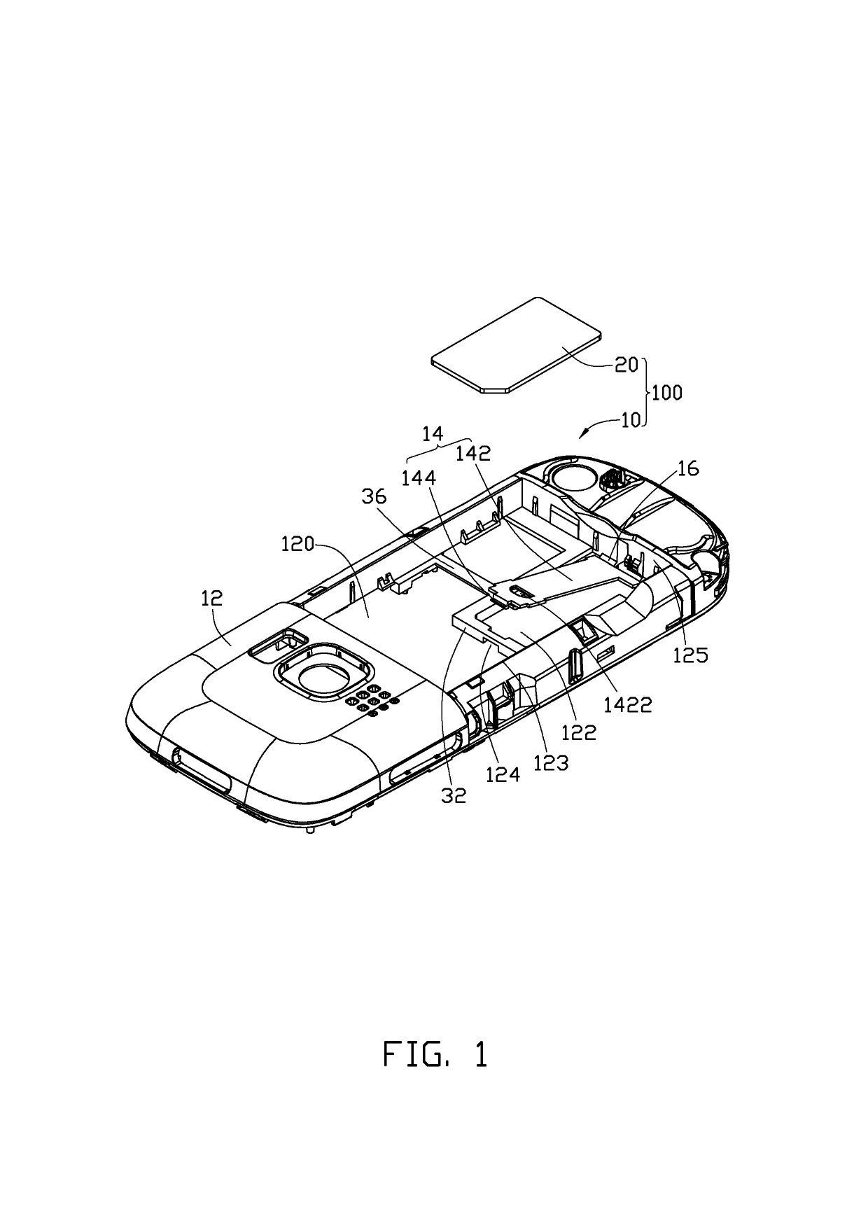

FIG. 1 shows a surface contact card holder 100 mounted on an electronic device. The surface contact card holder 100 includes a housing 10 and a latching cover 14 integrally formed on the housing 10 to receive a surface contact card 20.

The housing 10 may be a portion of the electronic device, and includes a main section 12. The main section 12 defines a battery receiving cavity 120 for receiving a battery. The battery receiving cavity 120 is defined by two opposite first sidewalls 123 and two opposite second sidewalls 125. A first beam 32 perpendicularly extends from one first sidewall 123, and a second beam 34 perpendicularly extends from adjacent to one second sidewall 125. The first beam 32 and the second beam 34 meet together to define a receiving space 122 for receiving the surface contact card 20. In order to stably secure the first beam 32 and the second beam 34, a strengthen beam 36 extends from the other first sidewall 123, and is connected to the second beam 34. The first beam 32 defines a latching slot 124.

The latching cover 14 is integrally formed on the second sidewall 125, and is connected to the second sidewall 125 by a connecting portion 16. The latching cover 14 includes a cover portion 142 and a latching end 144. The cover portion 142 can be rotated about the connecting portion 16. The latching end 144 is configured for selectively latching into the latching slot 124. In the exemplary embodiment, the cover portion 142 defines a locking slot 1422 to allow the cover portion 142 to be easily operated.

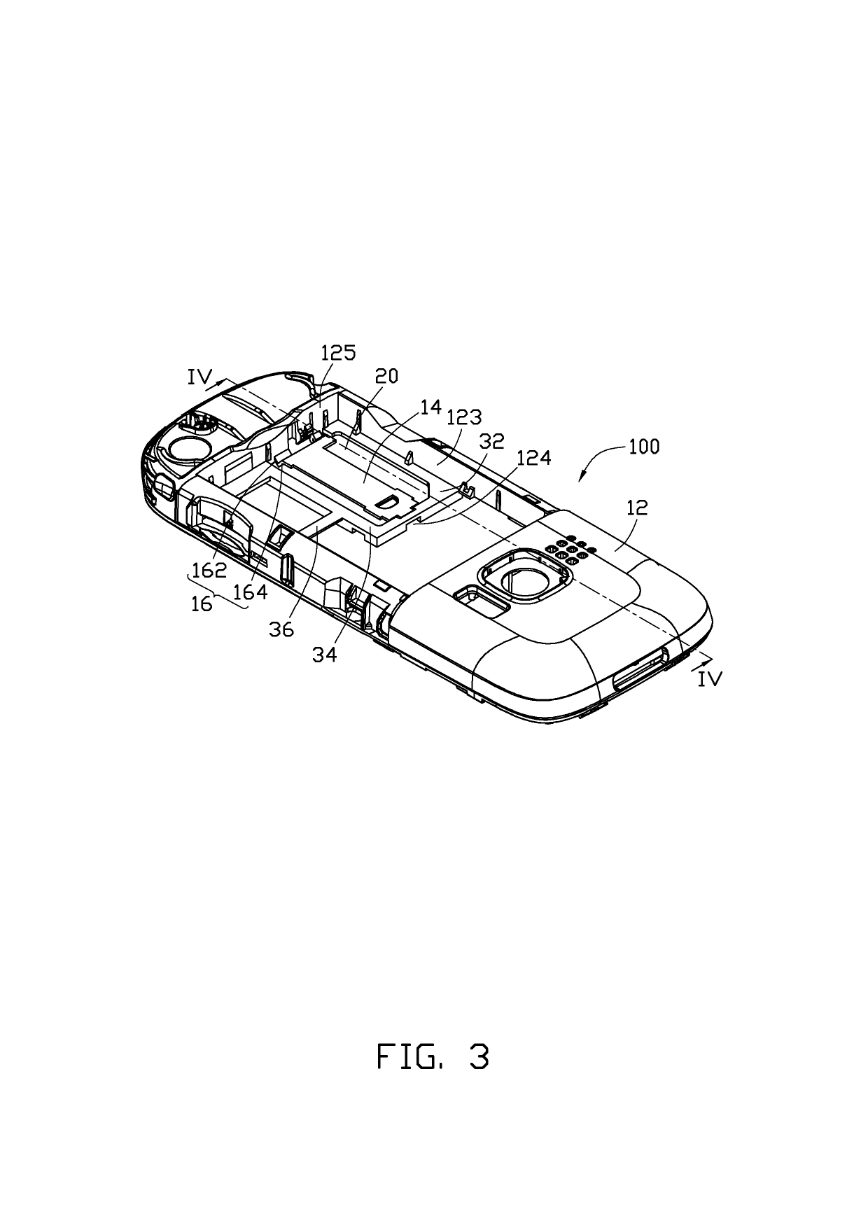

Referring to FIG. 3, the connecting portion 16 is flexibly connected to the second sidewall 125. The connecting portion 16 has a high elasticity allowing the latching cover 14 to bend relative to the second sidewall 125. The connecting portion 16 includes a first connecting plate 162 and a second connecting plate 162. In the exemplary embodiment, the first connecting plate 162 and the second connecting plate 162 are V-shaped or U-shaped.

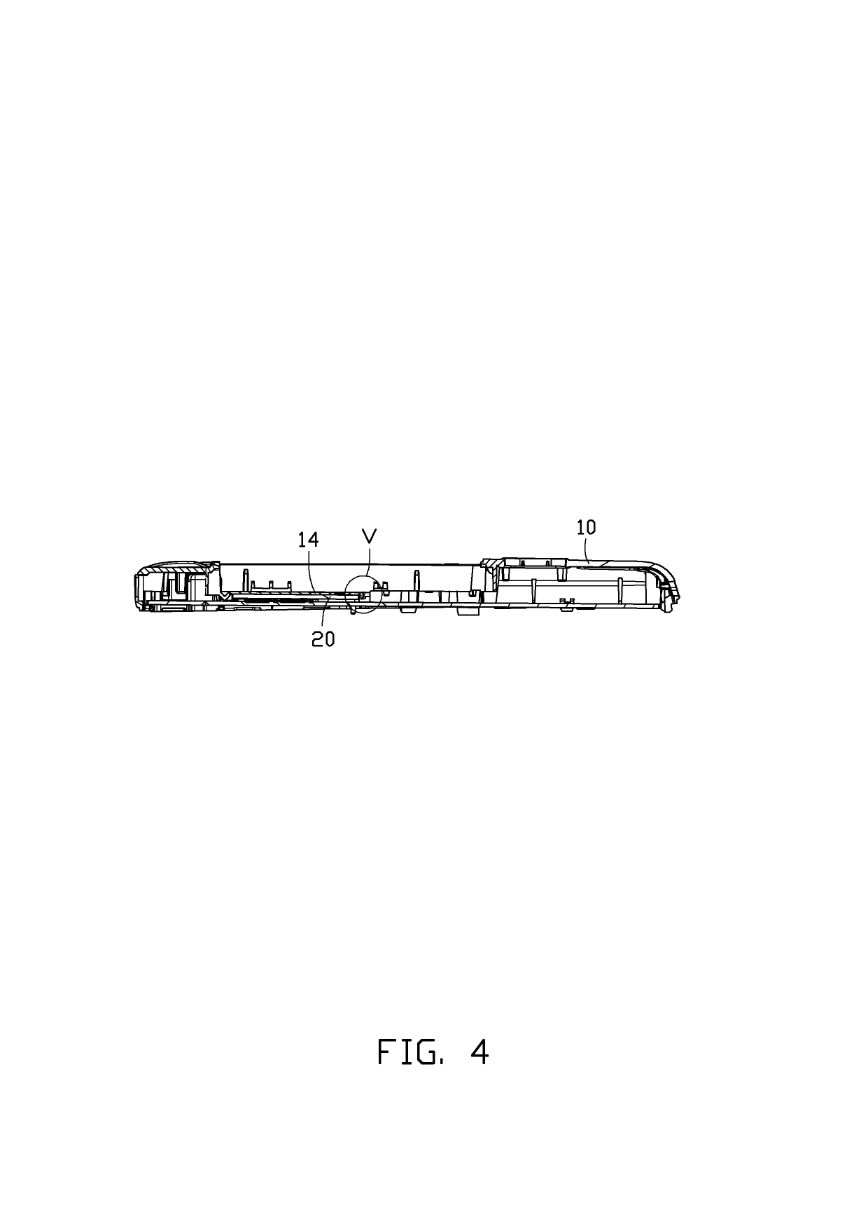

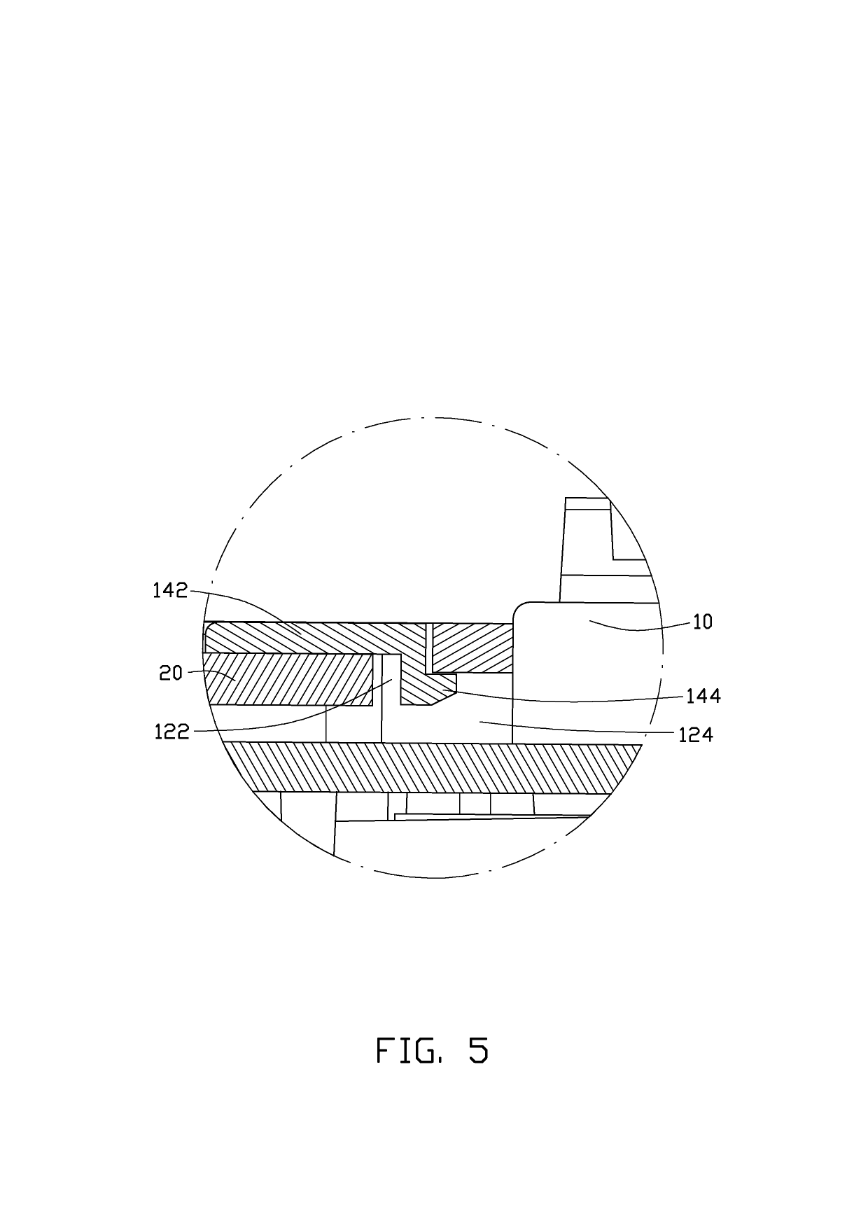

In use, referring to FIGS. 4 and 5, the surface contact card 20 is taken here as an exemplary application for the purposes of describing details of the surface contact holder 100. The surface contact card 20 is inserted into the receiving space 122 to allow the surface contact card 40 to resist against the first beam 32 and the second beam 34. The latching cover 14 is rotated about the connecting portion 16 and allows the latching end 144 to be latched in the latching slot 124. At the same time, the connecting portion 16 accumulates a predetermined elastic force for opening the latching cover 14, as described below. Thus, the surface contact card 20 is thereby held steadily in the housing 10.

To remove the surface contact card 20, referring to FIGS. 3 and 5, the cover portion 122 is pressed and pull the locking slot 1422 to move toward the connecting portion 16, the latching end 144 is moved out of the latching slot 123. The accumulated elastic energy of the connection portion 16 is released to rebound the latching cover 14 so that the latching cover 14 is automatically opened far away from the receiving space 122, and the surface contact card 20 is easily removed from the housing 10.

As described above, the exemplary embodiment provides a surface contact card holder for portable electronic devices, such as mobile phones. The surface contact card holder can be easily opened and is more user-friendly.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A surface contact card holder, comprising:
a housing defining a receiving space configured for receiving a surface contact card;
a latching cover for covering the receiving space, one end of the latching cover rotatably attached to the housing, another end of the latching cover selectively latched to the housing to allow insertion and removal of the surface contact card from the housing.

2. The holder as claimed in claim 1, wherein the housing defines a battery receiving cavity, the battery receiving cavity is defined by two opposite first sidewalls and two opposite second sidewalls, the latching cover is integrally formed on one of the second sidewalls.

3. The holder as claimed in claim 2, wherein a first beam perpendicularly extends from one of the first sidewalls, and a second beam perpendicularly extends from adjacent to one of the second sidewalls, the first beam and the second beam meet together to define a receiving space for receiving the surface contact card.

4. The holder as claimed in claim 3, wherein a strengthen beam extends from the other of the first sidewalls, and is connected to the second beam.

5. The holder as claimed in claim 3, wherein the first beam defines a latching slot, the latching cover includes a cover portion and a latching end, the cover portion is rotated about the connecting portion, the latching end for selectively latching into the latching slot.

6. The holder as claimed in claim 1, wherein the latching cover is connected to the housing, the connecting portion includes a first connecting plate and a second connecting plate, the first connecting plate and the second connecting plate are V-shaped.

7. A portable electronic device comprising:
a housing defining a receiving space;
a surface contact card configured for being received in the receiving space;
a latching cover for covering the receiving space, the latching cover rotatably attached to the housing by a connecting portion, the latching cover selectively latched to the housing to allow insertion and removal of the surface contact card from the housing.

8. The portable electronic device as claimed in claim 7, wherein the connecting portion includes a first connecting plate and a second connecting plate, the first connecting plate and the second connecting plate are V-shaped.

9. The portable electronic device as claimed in claim 7, wherein the housing defines a battery receiving cavity, the battery receiving cavity is defined by two opposite first sidewalls and two opposite second sidewalls, the latching cover is integrally formed on one of the second sidewalls.

10. The portable electronic device as claimed in claim 9, wherein a first beam perpendicularly extends from one of the first sidewalls, and a second beam perpendicularly extends from adjacent to one of the second sidewalls, the first beam and the second beam meet together to define a receiving space for receiving the surface contact card.

11. The portable electronic device as claimed in claim 10, wherein a strengthen beam extends from the other of the first sidewalls, and is connected to the second beam.

12. The portable electronic device as claimed in claim 11, wherein the first beam defines a latching slot, the latching cover includes a cover portion and a latching end, the cover portion is rotated about the connecting portion, the latching end for selectively latching into the latching slot.
